(19) United States
(12) Patent Application Publication
(10) Pub. No.: US 2023/0343934 A1
(43) Pub. Date: Oct. 26, 2023

(54) Method for Production of LixSiyOz Coatings Using a Single Source for Li And Si and Resultant Coated Products

(71) Applicants: BAR-ILAN UNIVERSITY, Ramat Gan (IL); TECHNION RESEARCH & DEVELOPMENT FOUNDATION LIMITED, Haifa (IL)

(72) Inventors: Malakhi NOKED, Tarum, D.N. Shimshon (IL); Yitzhak APELOIG, Haifa (IL); Yosi KRATISH, Haifa (IL); Dmitry BRAVO-ZHIVOTOVSKII, Haifa (IL); Rosy SHARMA, Ramat Gan (IL)

(21) Appl. No.: 17/797,763

(22) PCT Filed: Feb. 4, 2021
(86) PCT No.: PCT/IL2021/050133

§ 371 Date: Aug. 5, 2022

Related U.S. Application Data
(60) Provisional application No. 62/970,881, filed on Feb. 6, 2020.

(51) Int. Cl. H01M 4/36; C01G 53/00; H01M 4/58; H01M 4/505; H01M 4/525; H01M 4/04; C23C 16/40; C23C 16/455

(52) U.S. Cl. CPC H01M 4/366; C01G 53/50; H01M 4/5825; H01M 4/505; H01M 4/525; H01M 4/0428; C23C 16/401; C23C 16/45553; C23C 16/45555; C23C 16/45531; C01P 2006/40; C01P 2002/85; C01P 2002/90; C01P 2004/86; C01P 2004/04; C01P 2004/03; C01P 2002/89; H01M 2004/021

(57) ABSTRACT

Some exemplary embodiments of the invention relate to performing atomic layer deposition (ALD) or molecular layer deposition (MLD) of a volatile organo silyl lithium compound and ozone on a substrate. According to various exemplary embodiments of the invention the volatile organo silyl lithium compound includes SiLi₂tBuMe and/or tBuMe₂SiLi and/or tBuMe₂SiNa and/or SiLi₃Et and/or Alk₃GeLi and/or [(Alk₃Si)₄Al]Li and/or (NMe₂)(tBu)₂SiLi and/or tBuMe₂SiLi-TMEDA and/or SiLi+TMA₂tBuMe. Resultant coated products and their uses are also disclosed.

### CROSS REFERENCE TO RELATED APPLICATIONS

This PCT application claims the benefit according to 35 U.S.C. § 119 (e) of U.S. provisional application 62/970,881 filed on 6 Feb., 2020 and entitled “VAPOR PHASE DEPOSITION OF MULTI-COMPONENT NANO LAYER OF METALS AND METALOIDS OXIDE/NITRIDES/SULFIDES USING A SINGLE PRECURSOR FOR PROTECTION OF BATTERY ELECTRODES” which is fully incorporated herein by reference.

### FIELD OF THE INVENTION

Various described exemplary embodiments of the invention are in the field of thin film deposition, semi-conductors and electrochemistry.

### BACKGROUND OF THE INVENTION

NCM (nickel cobalt manganese) high energy cathodes for Li-ion batteries deliver a high capacity (>250 mAhrg⁻¹) and exhibit minor volume changes. However this family of layered materials suffers from voltage fading, irreversible capacity loss and prolonged cycling instability. The common source attributed to all failure mechanisms relates to the activation step, which occurs at >4.5 V and triggers a series of structural changes in the material. The inactive Li₂MnO₃ transforms from monoclinic to rhombohedral phase and interacts with the active NMC phase to form a metastable spinel interface, accompanied by the release of O₂ from the surface which leads to structural degradation, high voltage hysteresis, increased parasitic reactions and transition metal migration.

Atomic layer deposition (ALD) allows surface uniform surface coating on a wide variety of substrates. ALD is superior to conventional chemical methods and heat treatments in many respects and provides a tool for creating new artificial interphases for electrochemical systems, with different chemistries.

Detailed characterization of thin surface layers formed by ALD is limited with most commonly employed methods being X-ray photoelectron spectroscopy (XPS) and scanning and tunneling electron microscopy (SEM and TEM respectively). In recent years, solid state NMR spectroscopy (ssNMR) has been used to some extent for studying coating layers but it has not reached its full potential due to its limited sensitivity. This limitation may be removed by utilizing the high spin polarization of unpaired electrons in a process called dynamic nuclear polarization (DNP). In DNP, the high electron spin polarization is transferred to surrounding nuclear spins resulting in 10-10⁴ fold increase in sensitivity in ssNMR measurements. Such gains may enable extraction of 3D structural information on nanometer-thick surface layers.

### SUMMARY OF THE INVENTION

One aspect of some embodiments of the invention relates to the use of a volatile organo silyl lithium compound as an ALD or MLD (Molecular layer deposition) precursor providing two or more elements in a single compound (e.g. Si and/or Li and/or Al). According to one embodiment the single source for Li and Si is tBuMe₂SiLi. In some embodiments the volatile organo silyl lithium compound is delivered in alternating pulses with ozone and/or with nitrogen plasma and/or with water.

Another aspect of some embodiments of the invention relates to a LiₓSi_{y}O_{z} thin film deposited on a substrate. In various exemplary embodiments the substrate comprises 0.35Li₂MnO₃·0.65LiNi_{0.35}Mn_{0.45}Co_{0.20}O₂(HE-NMC) and/or lithium cobalt oxide (LiCoO₂) and/or Lithium Manganese Nickel oxide (LiNi_{0.5}Mn_{1.5}O₄) and/or LiNi₈Mn₁Co₁ and/or lithium titanate (LTO).

Still another aspect of some embodiments of the invention relates to a cathode based on 0.35Li₂MnO₃·0.65LiNi_{0.35}Mn_{0.45}Co_{0.20}O₂(HE-NMC), coated with a thin layer of LiₓSi_{y}O_{z}. In some embodiments coating is accomplished using tBuMe₂SiLi as an ALD precursor.

In some exemplary embodiments of the invention, the layer of LiₓSi_{y}O_{z} contributes to an improvement in electrochemical performance of the cathode.

For purposes of this specification and the accompanying claims, the term “organo silyl lithium compound” includes compounds in which Si (silicon) is replaced by Ge (germanium).

For purposes of this specification and the accompanying claims, the term “LiₓSi_{y}O_{z}” includes “LiₓGe_{y}O_{z}”.

For purposes of this specification and the accompanying claims, in the term “LiₓSi_{y}O_{z}” or “LiₓGe_{y}O_{z}”, each of X, Y and X is a number greater than 0.

For purposes of this specification and the accompanying claims, the term “TMEDA” indicates Tetramethylethylenediamine.

For purposes of this specification and the accompanying claims, the term “TMA” indicates Trimethylaluminium.

For purposes of this specification and the accompanying claims, the term “LCO” indicates lithium cobalt oxide.

In some exemplary embodiments of the invention there is provided a method including: performing atomic layer deposition (ALD) or molecular layer deposition (MLD) of a volatile organo silyl lithium compound and ozone on a substrate. In various embodiments the volatile organo silyl lithium compound includes at least one member of the group consisting of SiLi₂tBuMe, tBuMe₂SiLi, tBuMe₂SiNa, SiLi₃Et, Alk₃GeLi, [(Alk₃Si)₄Al]Li, (NMe₂)(tBu)₂SiLi, tBuMe₂SiLi-TMEDA and +SiLi₂tBuMe+TMA. Alternatively or additionally, in some embodiments the volatile organo silyl lithium compound include tBuMe₂SiLi. Alternatively or additionally, in some embodiments the substrate includes at least one item selected from the group consisting of an electrode material, a semiconductor material and a metal foil. Alternatively or additionally, in some embodiments the electrode material includes at least one item selected from the group consisting of 0.35Li₂MnO₃·0.65LiNi_{0.35}Mn_{0.45}Co_{0.20}O₂(HE-NMC), LCO, NCM 622, NCM85, LTO, TiO₂, LNMO, NVPF, and LNO. Alternatively or additionally, in some embodiments the substrate includes 0.35Li₂MnO₃·0.65LiNi_{0.35}Mn_{0.45}Co_{0.20}O₂(HE-NMC). Alternatively or additionally, in some embodiments the semiconductor material includes at least one item selected from the group consisting of Si wafers, TiO₂ particles, TiO₂ particles (Gd and S doped). Alternatively or additionally, in some embodiments the metal foil includes at least one item selected from the group consisting of copper (Cu) foil and Titanium (Ti) foil. Alternatively or additionally, in some embodiments the ALD occurs in a vacuum reactor. Alternatively or additionally, in some embodiments the volatile organo silyl lithium compound is maintained at ≥145° C. Alternatively or additionally, in some embodiments the vacuum reactor is maintained at a temperature of at least 75° C. Alternatively or additionally, in some embodiments the method employs an ALD cycle including at least 0.025 sec pulse time for substrate followed by a at least 30 s dwell time and at least 0.01 s long ozone pulse with at least 30 sec dwell time. Alternatively or additionally, in some embodiments the method includes purging the reactor between ALD cycles. Alternatively or additionally, in some embodiments the method includes purging the reactor between volatile organo silyl lithium compound pulses and ozone pulses.

In some exemplary embodiments of the invention there is provided article of manufacture including a substrate coated with LiₓSi_{y}O_{z}. In some embodiments the coating has a thickness of at least 2 nm. Alternatively or additionally, in some embodiments the coating has a thickness of 5 nm or less. Alternatively or additionally, in some embodiments the substrate is selected from the group consisting of 0.35Li₂MnO₃·0.65LiNi_{0.35}Mn_{0.45}Co_{0.20}O₂(HE-NMC), LCO, NCM 622, NCM85, LTO, TiO₂. LNMO, NVPF, LNO, Si wafers, TiO₂ particles (Gd and S doped), copper (Cu) foil and Titanium (Ti) foil. Alternatively or additionally, in some embodiments the article of manufacture exhibits a peak at 102.18 eV in X-ray photoelectron spectroscopy (XPS). Alternatively or additionally, in some embodiments the article of manufacture exhibits four silicon environments at 17 ppm, −20 ppm, −60 ppm, and −110 ppm in direct dynamic nuclear polarization (DNP) spectra with CPMG detection. Alternatively or additionally, in some embodiments the article of manufacture exhibits ¹H nuclei, at 33 ppm, 27 ppm, 20 ppm, and 1.85 ppm by indirect dynamic nuclear polarization (DNP).

In some exemplary embodiments of the invention there is provided a battery including an article of manufacture as described above as an electrode.

In some exemplary embodiments of the invention there is provided a battery including an article of manufacture as described above as an electrode, showing no signs of structural disintegration after 100 charge/discharge cycles as analyzed by high-resolution scanning electron microscopy (HR-SEM).

Some exemplary embodiments of the invention, relate to use of a volatile organo silyl lithium compound as a single source ALD precursor. In some embodiments the single source for Li and Si is tBuMe₂SiLi. Alternatively or additionally, in some embodiments the use is for generating an atomic layer deposition of a LiₓSi_{y}O_{z} thin film. Alternatively or additionally, in some embodiments ALD is used to coat 0.35Li₂MnO₃·0.65LiNi_{0.35}Mn_{0.45}Co_{0.20}O₂(HE-NMC).

In some exemplary embodiments of the invention there is provided a cathode based on 0.35Li₂MnO₃·0.65LiNi_{0.35}Mn_{0.45}Co_{0.20}O₂(HE-NMC), coated with a thin layer of LiₓSi_{y}O_{z}. In some embodiments coating was affected using tBuMe₂SiLi as an ALD precursor.

In some exemplary embodiments of the invention there is provided a method for improving the electrochemical performance of a 0.35Li₂MnO₃·0.65LiNi_{0.35}Mn_{0.45}Co_{0.20}O₂(HE-NMC) cathode, including creating a thin film layer thereon by ALD, using tBuMe₂SiLi as a precursor of Li and Si.

### BRIEF DESCRIPTION OF THE DRAWINGS

In the drawings:

FIG. 1A is a HR-TEM image of HE-NMC;

FIG. 1B is a HR-TEM image of HE-NMC coated particles according to an exemplary embodiment of the invention;

FIG. 1C is a magnified view of the area marked by a rectangle in FIG. 1B;

FIG. 1D is a HR-TEM image as in FIG. 1B with measurement points 1 and 2 marked;

FIG. 1E is an EDS profile (counts as a function of energy in KeV) of measurement point 1 from FIG. 1D;

FIG. 1F is an EDS profile (counts as a function of energy in KeV) of measurement point 2 from FIG. 1D;

FIG. 2A is the XPS spectra (Intensity in absorbance units as a function of binding energy in eV) of Si 2p for an LiₓSi_{y}O_{z} coated HE-NMC sample according to an exemplary embodiment of the invention;

FIG. 2B is the XPS spectra (Intensity in absorbance units as a function of binding energy in eV) of Ni 2p corresponding to the untreated (dark grey) and LiₓSi_{y}O_{z} coated HE-NMC (light grey) according to an exemplary embodiment of the invention;

FIG. 3 is a diagram of a proposed mechanism for the interaction of tBuMe₂SiLi with metal-oxide surface (hereinafter Scheme 1);

FIG. 4A is a comparative galvanostatic voltage profile (Voltage (Vs Li/Li⁺) as a function of specific capacity (mAh/g)) of 1st cycle obtained from the untreated (solid line) and treated (dashed line) Li|HE-NMC cell according to an exemplary embodiment of the invention, cycled at the rate of C/15 in 30 μL LP57 electrolyte solution;

FIG. 4B shows the comparative galvanostatic voltage profile (Voltage (Vs Li/Li⁺) as a function of specific capacity (mAh/g)) of 100th cycle obtained from the untreated (solid line) and treated (dashed line) Li|HE-NMC cell according to an exemplary embodiment of the invention, cycled at the rate of C/3 in 30 μL LP57 electrolyte solution;

FIG. 5 is a plot of average Voltage (Vs Li/Li⁺) as a function of cycle number for untreated (partially filled circles) and treated (empty circles) Li|HE-NMC cell according to an exemplary embodiment of the invention, cycled in 30 μL LP57 electrolyte solution;

FIG. 6A is a plot of differential capacity (dQ/dV (mAhg⁻¹V⁻¹)) versus potential (Vs Li/Li⁺) for the 1st cycle of the untreated (filled circles) and treated (unfilled circles) Li|HE-NMC half-cell according to an exemplary embodiment of the invention;

FIG. 6B is a plot of differential capacity (dQ/dV (mAhg⁻¹V⁻¹)) versus potential (Vs Li/Li⁺) for the 50th cycle untreated (filled circles) and treated (unfilled circles) Li|HE-NMC half-cell according to an exemplary embodiment of the invention;

FIG. 7 is a plot of discharge capacity (mAhg⁻¹) as a function of cycle number indicating cycling performance of the untreated (solid line) and treated (dashed line) HE-NMC according to an exemplary embodiment of the invention illustrating the effect of applied C-rates in Li|HE-NMC half-cell configuration with LP57 as the electrolyte solution;

FIG. 8A is an HR-SEM micrograph after 100 charge-discharge cycles at a rate of 1 C for an uncoated HE-NMC electrode;

FIG. 8B is an HR-SEM micrograph after 100 charge-discharge cycles at a rate of 1 C for a coated HE-NMC electrode according to an exemplary embodiment of the invention; and

FIG. 9A is a plot of the in-operando online electrochemical mass spectrometry response (V Li/Li⁺) for O₂ evolved (/10⁻⁹) as a function of applied potential (light dotted line; voltage profile indicating applied voltage at a given time) during galvanostatic cycling of the untreated (solid line) and treated (heavy dotted line) HE-NMC in Li|HE-NMC half-cell configuration with 75 μL of LP57 electrolyte solution;

FIG. 9B is a plot of the in-operando online electrochemical mass spectrometry response (V Li/Li⁺) for CO₂ evolved (/10⁻⁹) as a function of applied potential (light dotted line; voltage profile indicating applied voltage at a given time) during galvanostatic cycling of the untreated (solid line) and treated (heavy dotted line) HE-NMC in Li|HE-NMC half-cell configuration with 75 μL of LP57 electrolyte solution;

FIG. 9C is a plot of the in-operando online electrochemical mass spectrometry response (V Li/Li⁺) for H₂ evolved (/10⁻⁹) as a function of applied potential (light dotted line; voltage profile indicating applied voltage at a given time) during galvanostatic cycling of the untreated (solid line) and treated (heavy dotted line) HE-NMC in Li|HE-NMC half-cell configuration with 75 μL of LP57 electrolyte solution; and

FIG. 9D is a plot of the in-operando online electrochemical mass spectrometry response (V Li/Li⁺) for volatile fragments of LiPFr evolved (/10⁹) as a function of applied potential (light dotted line; voltage profile indicating applied voltage at a given time) during galvanostatic cycling of the untreated (solid line) and treated (heavy dotted line) HE-NMC in Li|HE-NMC half-cell configuration with 75 μL of LP57 electrolyte solution;

FIG. 10A is a HR-TEM image of HE-NMC particles coated with LiₓSi_{y}O_{z} according to another exemplary embodiment of the invention;

FIG. 10B is a HR-TEM image of TiO₂ coated with LiₓSi_{y}O_{z} according to another exemplary embodiment of the invention;

FIG. 11A is the XPS spectra (Intensity in absorbance units as a function of binding energy in eV) of Si 2p corresponding to the Ti foil substrate coated with tBuMe₂SiLi using N₂ Plasma according to another exemplary embodiment of the invention;

FIG. 11B is the XPS spectra (Intensity in absorbance units as a function of binding energy in eV) of N 1 s corresponding to the Ti foil substrate coated with tBuMe₂SiLi using N₂ Plasma according to another exemplary embodiment of the invention;

FIG. 12 is a STEM-HAADF (Scanning Transmission Electron Microscopy High-Angle Annular Dark-Field) image of tBuMe₂SiNa coated substrate of HE-NMC according to another exemplary embodiment of the invention;

FIG. 13 is the XPS spectra (Intensity in absorbance units as a function of binding energy in eV) of Ge 2p corresponding to the HE-NMC substrate coated with Alk₃GeLi according to another exemplary embodiment of the invention;

FIG. 14 is an EDS profile (counts as a function of energy in KeV) of a HENCM substrate coated with [(Alk₃Si)₄Al]Li according to another exemplary embodiment of the invention;

FIG. 15A is an EDS profile (counts as a function of energy in KeV) of a Gd and S doped TiO₂ substrate coated with (NMe₂)(tBu)₂SiLi according to another exemplary embodiment of the invention;

FIG. 15B is the XPS spectra (Intensity in absorbance units as a function of binding energy in eV) of Si 2p corresponding to the Gd and S doped TiO₂ substrate coated with (NMe₂)(tBu)₂SiLi according to an exemplary embodiment of the invention;

FIG. 15C is the XPS spectra (Intensity in absorbance units as a function of binding energy in eV) of N 1 s corresponding to the of a Gd and S doped TiO₂ substrate coated with (NMe₂)(tBu)₂SiLi according to an exemplary embodiment of the invention;

FIG. 16A is an EDS profile (counts as a function of energy in KeV) of Gd and S doped TiO₂ substrate coated with tBuMe₂SiLi-TMEDA according to an exemplary embodiment of the invention;

FIG. 16B is the XPS spectra (Intensity in absorbance units as a function of binding energy in eV) of Si 2p corresponding to the Gd and S doped TiO₂ substrate coated with tBuMe₂SiLi-TMEDA according to an exemplary embodiment of the invention;

FIG. 16C is the XPS spectra (Intensity in absorbance units as a function of binding energy in eV) of N 1 s corresponding to the Gd and S doped TiO₂ substrate coated with tBuMe₂SiLi-TMEDA according to an exemplary embodiment of the invention;

FIG. 17A is an EDS profile (counts as a function of energy in KeV) of TiO₂ substrate coated with dTrimethyl Aluminum an, SiLi₂tBuMe Ozone as a source of Li, Si, Al, and O respectively according to an exemplary embodiment of the invention;

FIG. 17B is the XPS spectra (Intensity in absorbance units as a function of binding energy in eV) of Si 2p corresponding to the TiO₂ substrate coated with Trimethyl, SiLi₂tBuMe Aluminum and Ozone as a source of Li, Si, Al and O respectively according to an exemplary embodiment of the invention;

FIG. 17C is the XPS spectra (Intensity in absorbance units as a function of binding energy in eV) of Al 2p corresponding to the TiO₂ substrate coated with Trimethyl, SiLi₂tBuMe Aluminum and Ozone as a source of Li, Si, Al and O respectively according to an exemplary embodiment of the invention;

FIG. 17D is an HR-TEM picture of coated TiO₂ particles coated with, SiLi₂tBuMe Trimethyl Aluminum and Ozone; and

FIG. 17E is an HR-TEM picture of TiO₂ particles coated with Trimethyl Aluminum and Ozone, SiLi₂tBuMe.

### DETAILED DESCRIPTION OF THE INVENTION

Embodiments of the invention relate to methods of Atomic Layer Deposition (ALD) which employ a single source for Li and Si and to resultant products. For purposes of this specification and the accompanying claims, the term “Atomic Layer Deposition” or “ALD” should be considered to include “Molecular layer deposition” or “MLD”. Specifically, some embodiments of the invention can be used to produce an LiₓSi_{y}O_{z} coating on a substrate. The principles and operation of a method and/or article of manufacture according to exemplary embodiments of the invention may be better understood with reference to the drawings and accompanying descriptions.

Before explaining at least one embodiment of the invention in detail, it is to be understood that the invention is not limited in its application to the details set forth in the following description or exemplified by the Examples. The invention is capable of other embodiments or of being practiced or carried out in various ways. Also, it is to be understood that the phraseology and terminology employed herein is for the purpose of description and is not limiting.

Some exemplary embodiments of the invention relate to the use of ALD with a novel alkyl lithium silicate single source precursor, to coat 0.35Li₂MnO₃·0.65LiNi_{0.35}Mn_{0.45}Co_{0.20}O₂ (HE-NMC). These embodiments exhibit a remarkable efficacy of this coating phase in terms of its effect on a cathode's electrochemical performance. Further provided is an in depth characterization of the novel coating layer utilizing high sensitivity DNP-ssNMR, as well as electron microscopy and XPS, as well as a structural model for this radically new lithium-silicon based surface protection layer.

Exemplary Methods

Some exemplary embodiments of the invention relate to a method including performing atomic layer deposition (ALD) or molecular layer deposition (MLD) of a volatile organo silyl lithium compound and ozone on a substrate. According to various exemplary embodiments of the invention the volatile organo silyl lithium compound comprises tBuMe₂SiLi and/or tBuMe₂SiNa and/or SiLi₃Et and/or Alk₃GeLi and/or [(Alk₃Si)₄Al]Li and/or (NMe₂)(tBu)₂SiLi and/or tBuMe₂SiLi-TMEDA and/or SiLi₂tBuMe-+Plasma₂ and/or tBuMe₂SiLi+N TMA. For purposes of this specification and the accompanying claims, the term “alkyl” or “Alk” indicates a functional group that contains only carbon and hydrogen atoms, which are arranged in a straight chain or branched chain (e.g. tBu) with the general formula CₙH₂ₙ₊₁.

In some exemplary embodiments of the invention, the volatile organo silyl lithium compound includes tBuMe₂SiLi.

Alternatively or additionally, in some embodiments the volatile organo silyl lithium compound includes tBuMe₂SiNa. Alternatively or additionally, in some embodiments the volatile organo silyl lithium compound includes SiLi₃Et. Alternatively or additionally, in some embodiments the volatile organo silyl lithium compound includes Alk₃GeLi. Alternatively or additionally, in some embodiments the volatile organo silyl lithium compound includes [(Alk₃Si)₄Al]Li. Alternatively or additionally, in some embodiments the volatile organo silyl lithium compound includes (NMe₂)(tBu)₂SiLi. Alternatively or additionally, in some embodiments the volatile organo silyl lithium compound includes tBuMe₂SiLi-TMEDA.

Alternatively or additionally, in some embodiments the volatile organo silyl lithium compound includeSiLi₂tBuMe+TMA.

Alternatively or additionally, according to various exemplary embodiments of the invention the substrate includes at least one item selected from the group consisting of an electrode material, a semiconductor material and a metal foil.

According to various exemplary embodiments of the invention the electrode material includes 0.35Li₂MnO₃·0.65LiNi_{0.35}Mn_{0.45}Co_{0.20}O₂(HE-NMC) and/or LCO and/or NCM 622 and/or NCM85 and/or LTO and/or TiO₂ and/or LNMO and/or NVPF and/or LNO. In some embodiments the substrate includes 0.35Li₂MnO₃·0.65LiNi_{0.35}Mn_{0.45}Co_{0.20}O₂(HE-NMC).

Alternatively or additionally, in some embodiments the substrate includes LCO.

Alternatively or additionally, in some embodiments the substrate includes NCM 622.

Alternatively or additionally, in some embodiments the substrate includes NCM85.

Alternatively or additionally, in some embodiments the substrate includes LTO. Alternatively or additionally, in some embodiments the substrate includes TiO₂. Alternatively or additionally, in some embodiments the substrate includes LNMO. Alternatively or additionally, in some embodiments the substrate includes NVPF. Alternatively or additionally, in some embodiments the substrate includes LNO.

Alternatively or additionally, according to various exemplary embodiments of the invention the substrate comprises Si wafers and/or TIO₂ particles and/or TiO₂ particles (Gd and S Doped). According to some exemplary embodiments of the invention the substrate includes Si wafers. Alternatively or additionally, according to some exemplary embodiments of the invention the substrate includes TIO₂ particles. Alternatively or additionally, according to some exemplary embodiments of the invention the substrate includes TiO₂ particles (Gd and S Doped).

Alternatively or additionally, according to various exemplary embodiments of the invention the substrate comprises copper (Cu) foil and/or Titanium (Ti) foil. In some embodiments the substrate includes copper foil. Alternatively or additionally, in some embodiments the substrate includes titanium foil.

Alternatively or additionally, in some embodiments the ALD occurs in a vacuum reactor. Alternatively or additionally, in some embodiments the volatile organo silyl lithium compound is maintained at ≥145° C. Alternatively or additionally, in some embodiments the vacuum reactor is maintained at a temperature of at least 75° C., at least 80° C., at least 90° C., at least 100° C., at least 110° C., at least 120° C., at least 150° C., at least 200° C., at least 250° C., or intermediate or higher temperatures. Alternatively or additionally, according to various exemplary embodiments of the invention the vacuum reactor is maintained at a temperature of less than 300° C., less than 275° C., less than 250° C., less than 200° C., less than 100° C., less than 90° C. or intermediate or lower temperatures. Alternatively or additionally, in some embodiments the ALD cycle includes at least 0.025 sec pulse time for substrate followed by a at least 30 s dwell time and at least 0.01 s long ozone pulse with at least 30 sec dwell time. Alternatively or additionally, in some embodiments the method includes purging the reactor between ALD cycles. Alternatively or additionally, in some embodiments the method includes purging the reactor between volatile organo silyl lithium compound pulses and ozone pulses.

Exemplary Articles of Manufacture

In some exemplary embodiments of the invention there is provided an article of manufacture including a substrate coated with LiₓSi_{y}O_{z}. In some exemplary embodiments of the invention, the coating has a thickness of at least 2 nm. Alternatively or additionally, in some embodiments the coating has a thickness of 5 nm or less. Alternatively or additionally, in some embodiments substrate includes 0.35Li₂MnO₃·0.65LiNi_{0.35}Mn_{0.45}Co_{0.20}O₂(HE-NMC) and/or LCO, NCM 622 and/or NCM85 and/or LTO and/or TiO₂ and/or LNMO and/or NVPF and/or LNO and/or Si wafers and/or TiO₂ particles (Gd and S Doped) and/or copper (Cu) foil and/or Titanium (Ti) foil.

In some exemplary embodiments of the invention, the substrate includes 0.35Li₂MnO₃·0.65LiNi_{0.35}Mn_{0.45}Co_{0.20}O₂(HE-NMC). Alternatively or additionally, in some embodiments the substrate includes LCO. Alternatively or additionally, in some embodiments the substrate includes NCM 622. Alternatively or additionally, in some embodiments the substrate includes NCM85. Alternatively or additionally, in some embodiments the substrate includes LTO. Alternatively or additionally, in some embodiments the substrate includes TiO₂. Alternatively or additionally, in some embodiments the substrate includes LNMO. Alternatively or additionally, in some embodiments the substrate includes NVPF. Alternatively or additionally, in some embodiments the substrate includes LNO. Alternatively or additionally, in some embodiments the substrate includes Si wafers. Alternatively or additionally, in some embodiments the substrate includes TiO₂ particles (Gd and S Doped). Alternatively or additionally, in some embodiments the substrate includes copper (Cu) foil. Alternatively or additionally, in some embodiments the substrate includes titanium (Ti) foil.

Alternatively or additionally, in some embodiments the article of manufacture exhibits a peak at 102.18 eV in X-ray photoelectron spectroscopy (XPS). Alternatively or additionally, in some embodiments the article of manufacture exhibits four silicon environments at 17 ppm, −20 ppm, −60 ppm, and −110 ppm in direct dynamic nuclear polarization (DNP) spectra with CPMG detection. Alternatively or additionally, in some embodiments the article of manufacture exhibits ¹H nuclei, at 33 ppm, 27 ppm, 20 ppm, and 1.85 ppm by indirect dynamic nuclear polarization (DNP).

In some exemplary embodiments of the invention there is provided a battery including an article of manufacture as described above as an electrode. In some exemplary embodiments of the invention, the electrode of the battery shows no signs of structural disintegration after 100 charge/discharge cycles as analyzed by high-resolution scanning electron microscopy (HR-SEM).

Exemplary Uses

Some exemplary embodiments of the invention relate to use of a volatile organo silyl lithium compound as a single source ALD precursor. Single source, as used here means that the compound provides both Li and Si. In some embodiments the single source for Li and Si is tBuMe₂SiLi. In some embodiments the use is applied to generating an atomic layer deposition of a LiₓSi_{y}O_{z} thin film. In some embodiments ALD is used to coat 0.35Li₂MnO₃·0.65LiNi_{0.35}Mn_{0.45}Co_{0.20}O₂(HE-NMC). In some exemplary embodiments of the invention, a cathode based on 0.35Li₂MnO₃·0.65LiNi_{0.35}Mn_{0.45}Co_{0.20}O₂(HE-NMC) coated with a thin layer of LiₓSi_{y}O_{z} is provided. In some embodiments coating is affected using tBuMe₂SiLi as an ALD precursor.

Alternatively or additionally, in some embodiments a method for improving the electrochemical performance of a 0.35Li₂MnO₃·0.65LiNi_{0.35}Mn_{0.45}Co_{0.20}O₂(HE-NMC) cathode is provided. The method includes creating a thin film layer thereon by ALD, using tBuMe₂SiLi as a precursor of Li and Si.

### Experimental Procedures

ALD Treatment Procedure

The Li-rich material, 0.35Li₂MnO₃·0.65LiNi_{0.35}Mn_{0.45}Co_{0.20}O₂(HE-NMC) was used as substrate electrode material. Atomic layer deposition (ALD) was performed using a laboratory synthesized, volatile organo silyl lithium compound (tBuMe₂SiLi), ozone and the HE-NMC material in a custom made, particle coating unit inside the Ultratech savannah 200 ALD vacuum reactor. The precursor and the reactor temperature were maintained at 145° C. and 250° C. respectively. Argon was used as a carrier gas. Base pressure of the reactor was 0.06 Torr and a base process pressure of 0.14 Torr was maintained via Ar (Maxima) gas flow. One ALD cycle consists of 0.025 sec pulse time for tBuMe₂SiLi followed by a 30 s dwell time and 0.01 s long ozone pulse with 30 sec dwell time. The reactor was purged for 15 sec in between the alternating pulses.

According to various exemplary embodiments of the invention the substrate includes at least one member of the group consisting of 0.35Li₂MnO₃·0.65LiNi_{0.35}Mn_{0.45}Co_{0.20}O₂(HE-NMC), LCO, NCM 622, NCM85, LTO, TiO₂, LNMO, NVPF, LNO, Si wafers, TiO₂ particles (Gd and S Doped), TiO₂ particles copper (Cu) foil and Titanium (Ti) foil. Alternatively or additionally, in various exemplary embodiments of the invention the volatile organo silyl lithium compound includes at least one member of the group consisting of SiLi₂etBuM, tBuMe₂SiNa, SiLi₃Et, Alk₃GeLi, [(Alk₃Si)₄Al]Li, (NMe₂)(tBu)₂SiLi, tBuMe₂SiLi-TMEDA and SiLi₂tBuMe+AlMe₃ (TMA). Alternatively or additionally, according to various exemplary embodiments of the invention ozone and/or nitrogen plasma and/or water are applied to a selected substrate in alternating pulses with a selected organo silyl lithium compound.

Characterization Techniques

XPS was carried out using Kratos Analytical (England) AXIS-Ultra DLD with monochromic Al Kα (1486.6 eV) X-ray beam radiation. The binding energy of adventitious carbon at 285.0 eV was taken as an energy reference for all the measured peaks. HR-TEM examinations were carried out with a W-200 KV JEOL JEM-2100 transmission electron microscope operated at 200 kV. Specimen of coated and uncoated powders were suspended in isopropyl alcohol and then dried under vacuum at RT. HR-TEM images were collected from various particles in the samples.

STEM examinations were carried out with a FEI TITAN transmission electron microscope operated at 300 kV. Images and EDS profiles were collected from various particles in the samples.

Electrochemical Measurements

Composite electrodes were prepared by coating slurry with a composition of 80% HENMC, 5% Super P carbon black, 5% KS 6 graphite, and 10% PVDF solution in NMP, over Al foil. The electrode loading of ˜3 mg·cm⁻² was achieved. Coin cells of 2032-type were assembled with Li-metal counter electrodes (ø14 mm), two Celgard 2500 polypropylene separator (ø19 mm), and 1 M LiPF₆ solution in 3:7 ethylene carbonate: ethyl methyl carbonate (LP57). All cells were subjected to electrochemical cycling at 30° C. Currents for C-rates were calculated considering the specific capacity of HE-NMC as 250 mAhg⁻¹. The electrochemical measurements were carried out using BCS-805 battery cycler (Bio-logic Science instruments) in a potential window of 2.0 V-4.7 V. The first charge-discharge was carried out at C/15 with 4.7 V as the cut off voltage. Further cycling was carried out at different C-rate with upper cut off voltage of 4.6 V.

Analysis of evolving gases during the charge discharge cycles was achieved using in-operando online electrochemical mass spectrometer (OEMS) (Hiden Analytical). Cells for the OEMS measurement were assembled inside Ar filled glovebox with HE-NMC as cathode (o 12 mm), Li as anode (ø14 mm), and 200 μL LP57 as electrolyte solution. Two polypropylene separators (ø29 mm) were placed between cathode and anode. The cell was then taken out of the glove box and was connected to OEMS capillary using one of the Swagelok valves located at the head part of the cell. The electrochemical measurements were carried out using VSP— potentiostat (Bio-logic Science instruments) in a potential window of 4.7-2V at different C rates. The variation of desired gases with time was investigated using Mid mode.

Dynamic Nuclear Polarization (DNP)

Detection of thin surface layers which are impossible to detect with ssNMR due to its limited sensitivity is feasible using dynamic nuclear polarization (DNP) using exogenous nitroxide biradicals (TEKPol). The experimental approach for DNP is schematically depicted and explained in a paper co-authored by the inventors (Rosy et al. Energy Storage Materials 33 (2020) 268-275; fully incorporated herein by reference). Rosy et al. demonstrate that high sensitivity of DNP facilitates acquisition of ⁷Li as well as ²⁹Si and ¹³C spectra at natural isotopic abundance and determination of the local environments in the coating layer. Rosy et al. also demonstrate that detection of the Si species in the coating is enabled by DNP.

### Example 1

### Characterizations of ACEI: Morphology and Composition Analysis

Precursor Characterizations

Surface Analysis Using HR-TEM and XPS

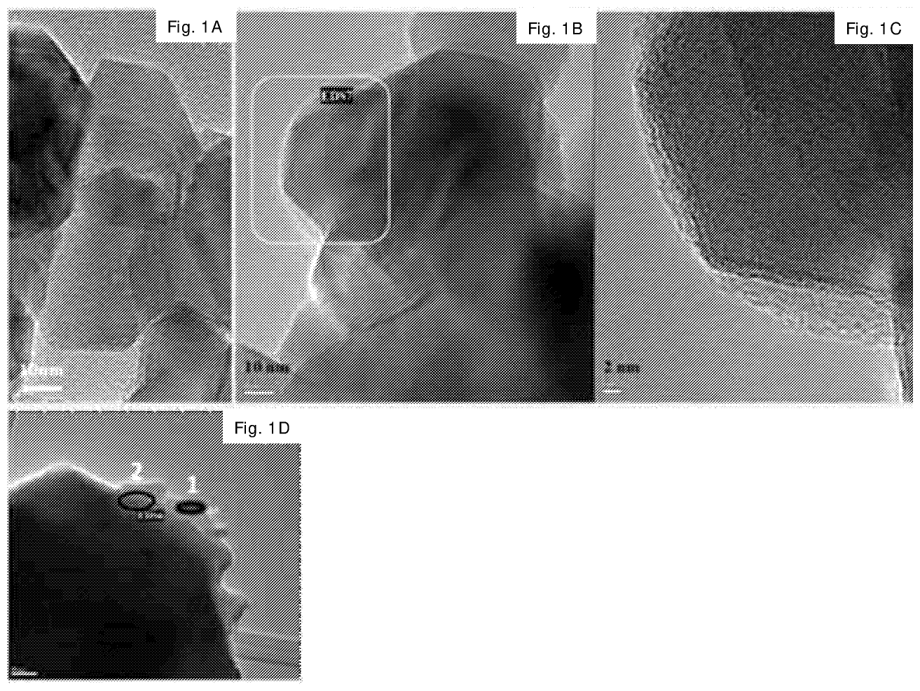

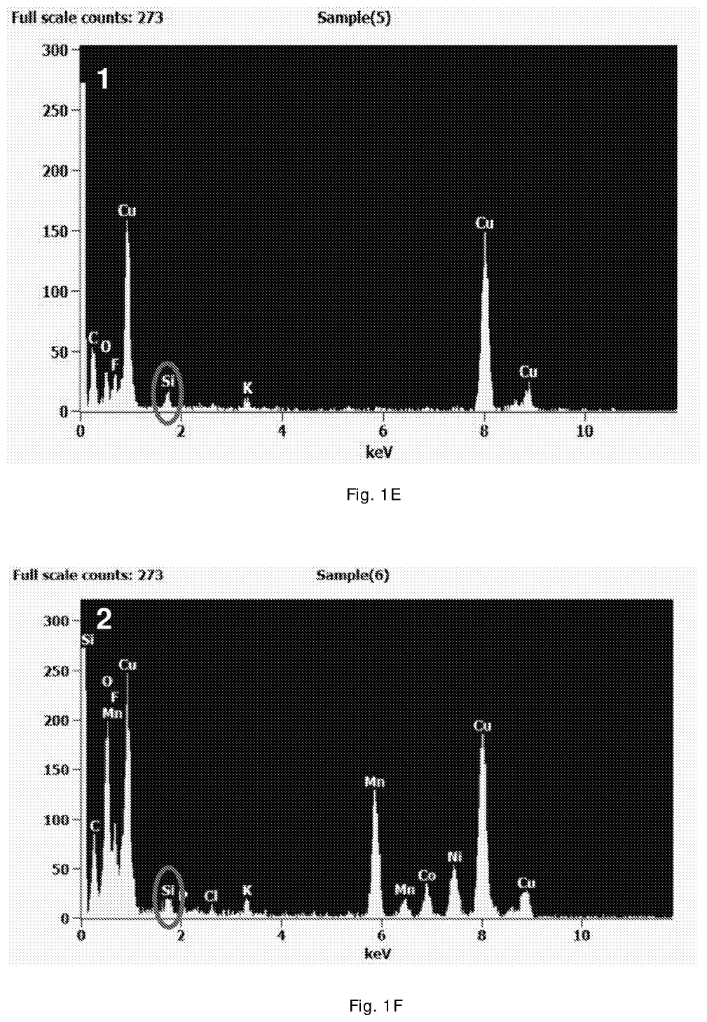

In order to examine the coating conformality, coverage and effects on the surface of the HENMC material HR-TEM analysis was performed. A thickness of 2-5 nm was observed on all particles. The coating shown in FIG. 1 seemed to cover different facets of the particle with different thicknesses. This is attributed to the complexity of the target particle structure. NCM particles has different facing surface atoms depended on the crystallographic plane (i.e. the (110) plane has TM (mostly Mn), O and Li exposed to the surface unlike the (104) plane which has TM and O exposed to the surface, which affect the chemical reaction of the ALD precursor.

FIG. 1A, FIG. 1B, FIG. 1C and FIG. 1D are HR-TEM images of HE-NMC. FIG. 1A is an uncoated control particle. FIG. 1B is a coated particle according to an exemplary embodiment of the invention. FIG. 1C is a magnification of the area indicated by a rectangle in FIG. 1B showing the coating in greater detail. FIG. 1D is another HR-TEM image of a coated particle according to an exemplary embodiment of the invention with measurement points (1) and (2) indicated.

FIG. 1E and FIG. 1F are EDS profiles of measurements points (1) and (2) from FIG. 1D.

In FIG. 1D the coating on the edge of the particle is seen and 2 EDS points are marked for measurement. Si is observed only on the surface layer and no transition metals from the particle are present in the layer further confirms a coating layer. EDS profile 2 from the particle shows transitions metals and Si, all Si in the sample comes from the coating.

Energy Dispersive X-ray Spectroscopy (EDS) is an analytical technique equipped in the HR-TEM instrument to detect elements present on the surface of the sample. The results show the presence of Si, Al or N in the coated sample.

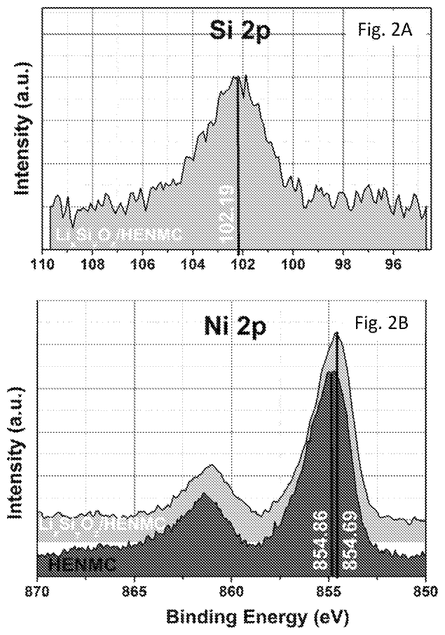

Composition of the deposited film was next investigated using X-ray photoelectron spectroscopy (XPS). The presence of Si was confirmed by the existence of peak at 102.18 eV in the Si 2p spectra (FIG. 2A). The binding energy values of Si 2p indicated the presence of LiₓSi_{y}O_{z} on the surface and confirmed the practical applicability of the custom made single-source bifunctional precursor for the atomic scale deposition of Si-based thin films.

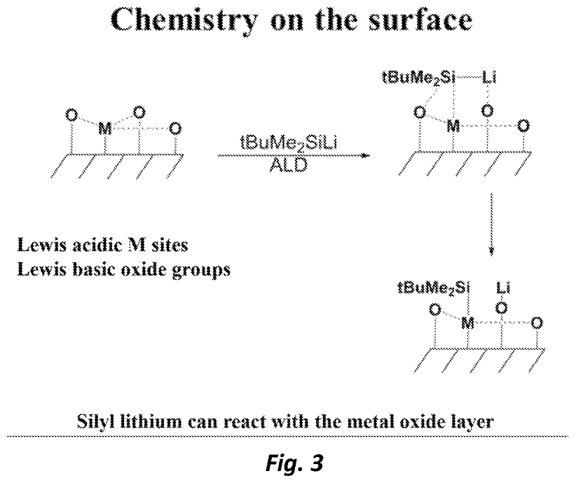

Interestingly, the Ni 2p peak in the coated sample exhibited a negative shift of 0.17 eV (FIG. 2B) which indicated the altered electronic configuration of transition metals in the near surface region, which can be explained on the basis of chemical interaction between the metal ions and the precursor molecule as proposed in Scheme 1 (FIG. 3). Although, the presence of Li was observed in the Li1 s XPS spectra, nothing conclusive can be inferred from it, keeping in mind the contribution of Li from the HE-NMC. Consequently, building on the capabilities of ssNMR to differentiate inner and outer surface contributions, in-depth ssNMR-DNP measurements were next carried out to confirm the presence of Li and for the detailed structural analysis of the deposited film.

Direct DNP spectra with CPMG detection in Rosy et al. reveals four silicon environments at 17, −20, −60, and −110 ppm. These resonances were assigned to different alkylated silicon groups, R₃SiO—R′, R₂Si(OSi)₂, RSi(OSi)₃ and Si(OSi)₄, respectively (R=alkyl group and R′=alkyl or OH). Polarization transfer through the ¹H nuclei, resulted in ²⁹Si signal enhancement of 53 and increased contribution of the double and mono alkylated (−20 and −60 ppm, respectively) silicon resonances. This enhancement suggests these moieties are located on the outer surface of the coating, making them easily accessible to polarization transfer from the radicals and the solvent. The amorphous silica group, resonating at −110 ppm is most likely located at the interface between the alkylated silicon groups and the TiO₂ substrate. Its low contribution suggests it is a thin layer further away from the radical's solution.

Rosy et al. reports that four ¹³C resonances were detected by indirect DNP from ¹H nuclei, at 33, 27, 20 and 1.85 ppm. These were assigned to the carbons in the t-butyl and methyl groups (CH₃—C—Si- and CH₃—Si-groups). Finally, ⁷Li species in the coating were detected through direct DNP and could also be detected in ¹H-⁷Li CP experiment, but only when μwaves were used. This suggests that Li sites are distributed throughout the coating layer and are exposed to the solvent.

### Example 2

### Electrochemical Investigations

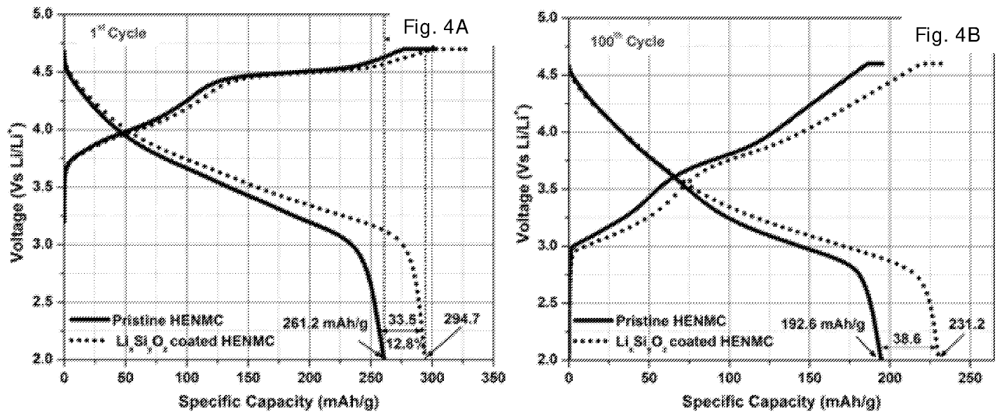

The comparative galvanostatic charge/discharge profile for the first and 100th cycle corresponding to both pristine and LiₓSi_{y}O_{z} coated HE-NMC electrodes are presented in FIG. 4A and FIG. 4B.

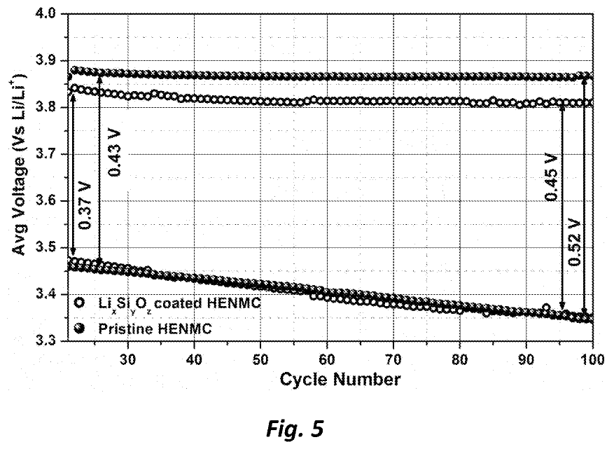

From the voltage profile of the first cycle (FIG. 4A), it can be seen that both the materials exhibited similar patterns during charge and discharge with an initial sharp rise in the voltage till 3.7 V, followed by a gradual increase till 4.4 V, and ultimately a long plateau at 4.5 V ascribed to the activation of Li₂MnO₃. During discharge lithium intercalation of the transition metal and Li⁺ layer takes place. Despite the similar nature of the voltage profiles, especially during the charging step, comparison of FIG. 4A (which shows the comparative galvanostatic voltage profile of 1st cycle) with FIG. 4B (which shows the comparative galvanostatic voltage profile of 100th cycle) obtained from the untreated (solid line) and treated (dashed line) Li|HE-NMC cell, cycled at the rate of C/15 and C/3, respectively in 30 μL LP57 electrolyte solution) reveals that coating according to an exemplary embodiment of the invention significantly enhanced the lithium insertion kinetics. This is demonstrated by the decreased voltage hysteresis and substantially improved discharge capacity. LiₓSi_{y}O_{z} coated HE-NMC demonstrated 33.5 mAh/g (˜12.8%) higher discharge capacity in comparison to the pristine sample during the first cycle. Interestingly, after 100 charge-discharge cycles, the difference in the discharge capacity of the uncoated and coated sample was increased to 20% (38.6 mAh/g) which manifests the ability of the proposed coating to stabilize the electrode material during prolong cycling. On the other hand, FIG. 5 illustrates the variation in mean voltage as a function of cycle number (as a plot showing the variation of average voltage with cycle number for untreated (partially filled circles) and treated (empty circles) Li|HE-NMC cell, cycled in 30 μL LP57 electrolyte solution), gives clear insight towards the improved lithiation/delithiation kinetics which can be concluded from the 60-70 mV lower voltage hysteresis for the coated sample. Additionally, only 2% of the irreversible capacity loss was witnessed for the coated sample in comparison to ˜11% for untreated sample (excluding the contribution of the constant voltage step). This substantial decrease in the irreversible capacity loss further reveals the multi-functional roles of the proposed protection layer in improving the electrochemical behavior and suppressing the parasitic reactions occurring at the electrode/electrolyte interface.

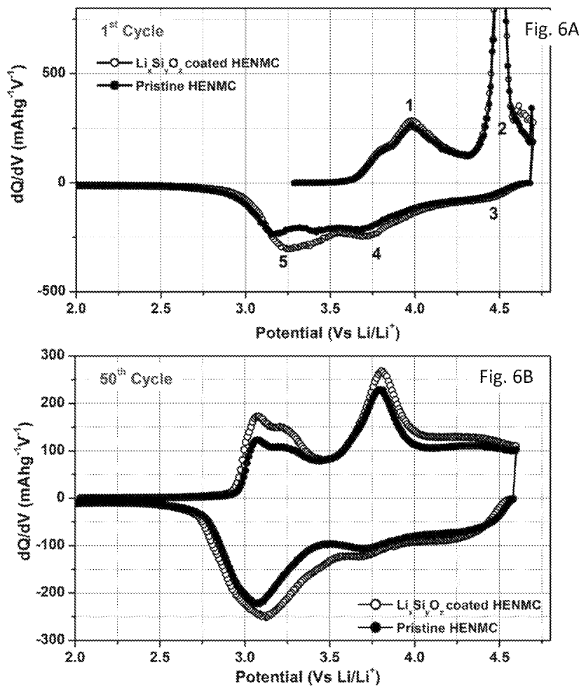

Further details on the Li intercalation/de-intercalation were obtained by plotting dQ/dV plots. FIG. 6A and FIG. 6B depict the derivative capacity plots for the 1^{st} and 50th cycles. In accordance with the previously reported literature, dQ/dV plot for the first cycle exhibits 5 peaks which are labelled in FIG. 6A. Peak 1 at ˜4.0 V can be ascribed to the delithiation of Li⁺ layer accompanied by the oxidation of Ni²⁺/Co³⁺ to Ni⁴⁺/Co⁴⁺ oxidation states. Next, the sharp peak at ˜4.5 V labelled as ‘2’ represents the characteristic activation peak of HE-NMC. This peak is associated with many complex processes, some of which are electrochemical activation of Li₂MnO₃ with the formation of MnO₂, the release of O₂ as well as structural transformation involving partial migration of TM to the interstitials of Li⁺ layer. While traversing with negative currents, peak 3 and 4 can be assigned to the lithiation of TM layer whereas, peak 5 can be accredited to the lithium insertion in Li⁺ layer. On comparing the dQ/dV plots of the coated and uncoated sample, sharp and well defined peaks corresponding to coated material can be clearly noticed which highlights the stable electrochemical behavior of the coated material in comparison to the untreated one.

Furthermore, the shift of peak 4 and 5 to higher potentials in case of coated samples indicates the facilitated insertion of lithium in both TM and Li⁺ layer. The sustained enhancement of the peak intensity with well-preserved peak shapes even after 50th (FIG. 6B) charge/discharge cycles, further indicate the apparent improvement in the electrochemical performance of the coated material. Additionally, the shift of peak 5 towards higher potential in the LiₓSi_{y}O_{z} coated sample indicates the suppression of spinel phase proliferation and supports the facile kinetics of lithiation during discharge.

The improved specific capacity, lower voltage hysteresis, and, faster intercalation/deintercalation kinetics of the coated sample as concluded from the above discussed electrochemical studies, hints towards the improvements in the rate capabilities.

### Example 3

### Performance of Coated Sample as a Function of Increasing Current Densities

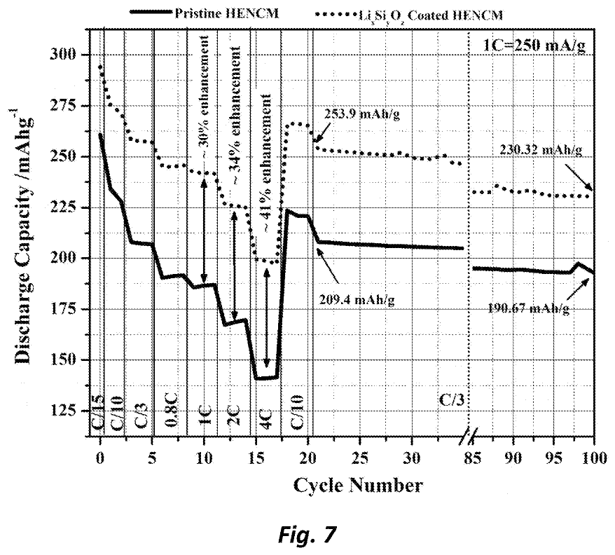

To further support the inferences obtained from the preliminary electrochemical data, the performance of the coated sample was studied as a function of increasing current densities (C-Rate). FIG. 7 presents the variation of discharge capacity with the increasing C-Rates in the range of C/10-4 C. In general, a decrease in the specific discharge capacity was observed with the increasing current densities for both the samples which can be explained on the basis of incomplete use of the active material at high currents. However, under all the investigated rates, LiₓSi_{y}O_{z} unequivocally outperformed in comparison to the uncoated sample. Yet, the most interesting finding was the substantial improvement at higher rates. The LiₓSi_{y}O_{z} coated HE-NMC exhibited the maximum enhancement in performance at a rate of 4 C (˜41% higher discharge capacity). This observation is in contrast to the usual trends observed with other coating compositions, as under such aggressive conditions of Li⁺ insertion/extraction, coating layers themselves undergo fractures and thus results in retarded performance. Consequently, the remarkably high discharge capacities of 243, 227 and 200 mAh/g demonstrated by LiₓSi_{y}O_{z}-HE-NMC in comparison to 186, 169 and 140 mAh/g for the uncoated sample at a rate of 1 C (250 mA/g), 2 C (500 mA/g) and 4 C (1000 mA/g) respectively, reveals the efficacy of the coating layer in preserving the structural integrity of the electrode material while facilitating the sustainable Li⁺ insertion/extraction under severely demanding working conditions.

### Example 4

### Structural and Morphological Changes

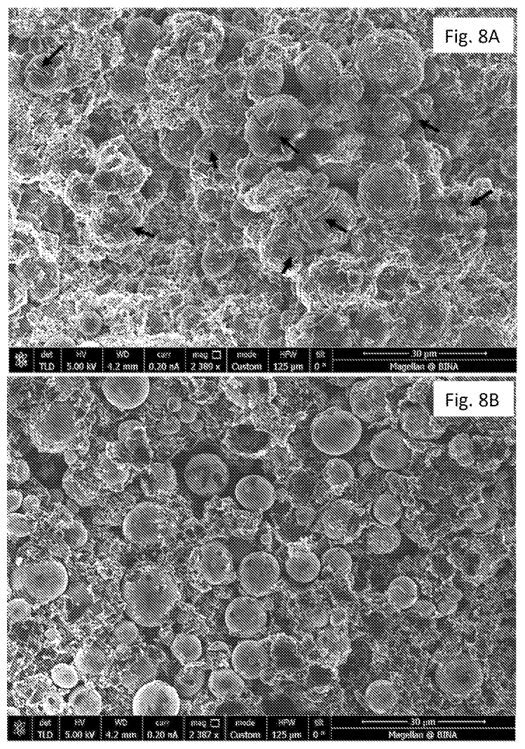

In order to elucidate a clear picture of the structural and morphological changes, a post-mortem analysis of the cycled electrodes carried out, exploiting the high-resolution scanning electron microscopy (HR-SEM). HR-SEM micrographs of the pristine electrodes after 50th cycle are presented in FIG. 8A and coated electrodes according to an exemplary embodiment of the invention 100th cycle are presented in FIG. 8B. The micrographs clearly show that the spheres corresponding to the uncoated HENCM (FIG. 8A) developed multiple cracks just after 50 charge/discharge cycles. The number and depth of the cracks were found to be further increased in the sample completing 100 cycles (not shown). In sharp contrast LiₓSi_{y}O_{z} coated HE-NMC according to an exemplary embodiment of the invention showed no signs of structural disintegration even after 100 charge/discharge cycles (FIG. 8B). Thus, HR-SEM micrographs add visual support to the conclusion regarding the efficacy of proposed LiₓSi_{y}O_{z} protection layer in improving the electrochemical performance while maintaining structural integrity.

### Example 5

### Gas Evolution

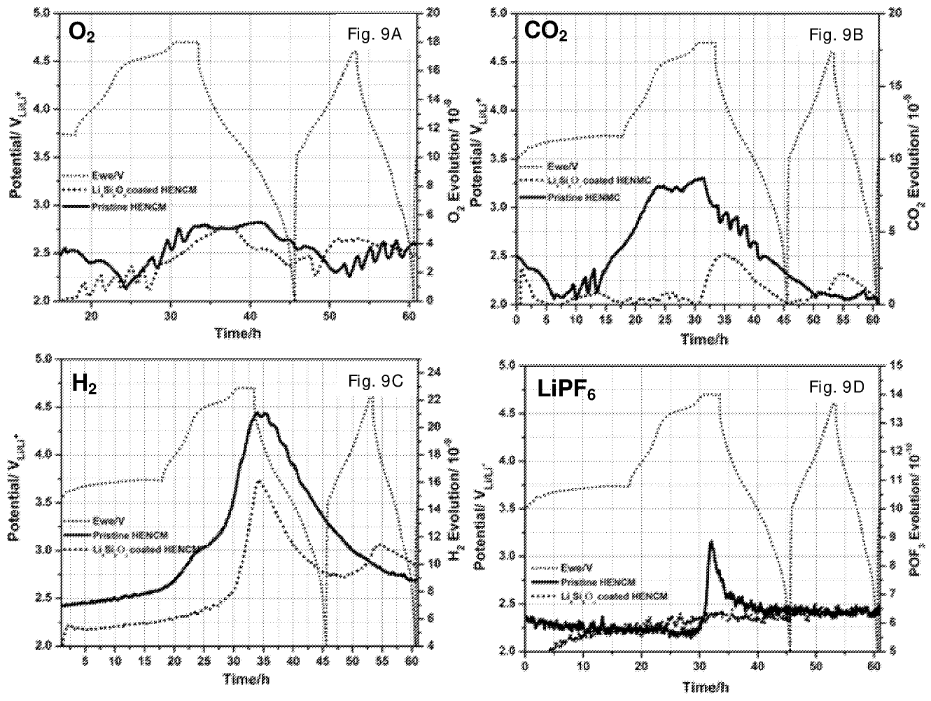

Building on the previous reports, the structural breakdown of the spherical particles (as observed from the HR-SEM images) can be ascribed to the evolution of gaseous species from HE-NMC during battery charging. The well-preserved morphology of the particles in the coated samples indicate towards the reduced strain which can be related to the lower gaseous evolution. Therefore, an in-operando analysis of the gases evolved during cycling carried out using online electrochemical mass spectrometry (OEMS) and the evolution from both the coated and uncoated sample was compared. The comparative evolution profiles for O₂ (FIG. 9A), CO₂ (FIG. 9B), H₂ (FIG. 9C), and POF₃ (FIG. 9D) as a function of applied potential are presented. From FIG. 9A it is observed that the O₂ evolution is initiated during the 4.5 V plateau and is substantially suppressed for the coated sample. The lower O₂ release in the coated sample manifests the efficacy of the alkylated LiₓSi_{y}O_{z} artificial cathode electrolyte interface (ACEI) in mitigating oxygen loss from the near surface of the cathode material while preserving the anionic redox activity. On the other hand, noticeable suppression in the CO₂ evolution was observed for the coated sample which indicates the suppressed parasitic reactions and electrolyte degradation on the electrode/electrolyte interface under high voltage plateaus. The similar interpretation was made from the significantly lower H₂ evolution by the coated sample. It is important to emphasize here that we are not eliminating the H₂ contribution from the anode side attributed to crosstalk of H⁺ to the lithium surface where it undergoes reduction to release H₂. But it should be kept in mind that since the size of the lithium anode and the current density used is similar for both the cases, a similar contribution should be expected to arise from the anode. So, despite the anode participation in the H₂ evolution, the considerable difference in H₂ evolution can be assigned to the differences produced by the presence and absence of the coating layer. Furthermore, the absence of POF₃ evolution arising from the breakdown of the LiPF₆ in the coated sample indicates suppressed electrolytic degradation in the presence of proposed artificial cathode electrolyte interface. The reduced evolution of the gases can be explained on the basis of the buffering effect of the amorphous thin film which act as a barrier and delays the exposure of the evolving oxygen to the electrolyte and thus suppresses the parasitic reactions. To summarize, the OEMS analysis depicted much impeded degradation of the electrolyte solution (both solvent and salt) in the coated sample revealing the importance of protection thin film (ACEI) in buffering/delaying the side reaction between the electrode and electrolyte and controlling the increasing interfacial resistance as well as overpotential attributed to the deposition of by-products on the electrode surface.

As will be apparent to the skilled person from the foregoing, the application of volatile organo silyl lithium compound as an unconventional, single source ALD precursor has been demonstrated. Using tBuMe₂SiLi as a single source for Li and Si, the invention provides a simple and facile protocol for the atomic layer deposition of LiₓSi_{y}O_{z} thin film. Utilizing the high sensitivity of DNP-ssNMR technique, an in-depth chemical and structural characterization of 2-5 nm thin LiₓSi_{y}O_{z} film was carried out, thereby evidencing the utility of this technique. In addition, with the electrochemical and spectroscopic evidences, the application of LiₓSi_{y}O_{z} thin film as a cathode protection layer for HE-NMC was shown, which not only serve as a helping hand in mitigating the structural and chemical degradation but also improves the battery kinetics. In contrast to conventional coating, the LiₓSi_{y}O_{z} thin film substantially outperforms the pristine material at faster lithiation/dilithiation rates by demonstrating ˜40% higher capacity at 4 C in comparison to the uncoated material.

### Example 6

### Coated Particles of HENCM and TiO₂

In order to demonstrate the applicability of ALD to coating semiconductor materials the ALD treatment procedure presented above was applied to HE-NMC and TiO₂ particles.

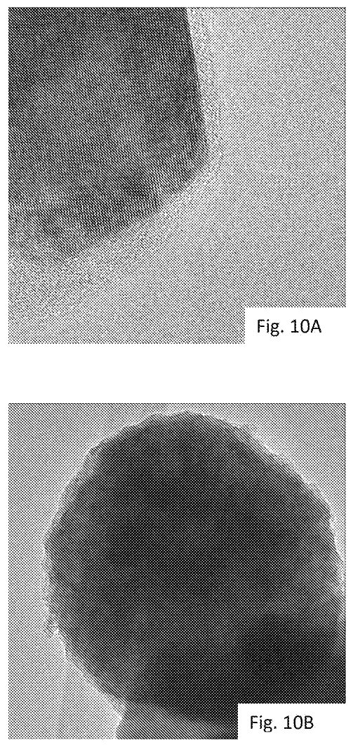

FIG. 10A is a HR-TEM image of HE-NMC coated particles according to another exemplary embodiment of the invention. FIG. 10B is a HR-TEM image of coated TiO₂ particles.

These results show that HE-NMC and TiO₂ are suitable substrates for additional embodiments of the invention using a variety of coating materials as described hereinabove.

### Example 7

### tBuMe₂SiLi Used to Deposit Lithiated Silicon Nitrides on Ti Foil

In order to demonstrate the applicability of ALD to coating metal foils, the ALD treatment procedure presented above was used to apply tBuMe₂SiLi to Ti foil.

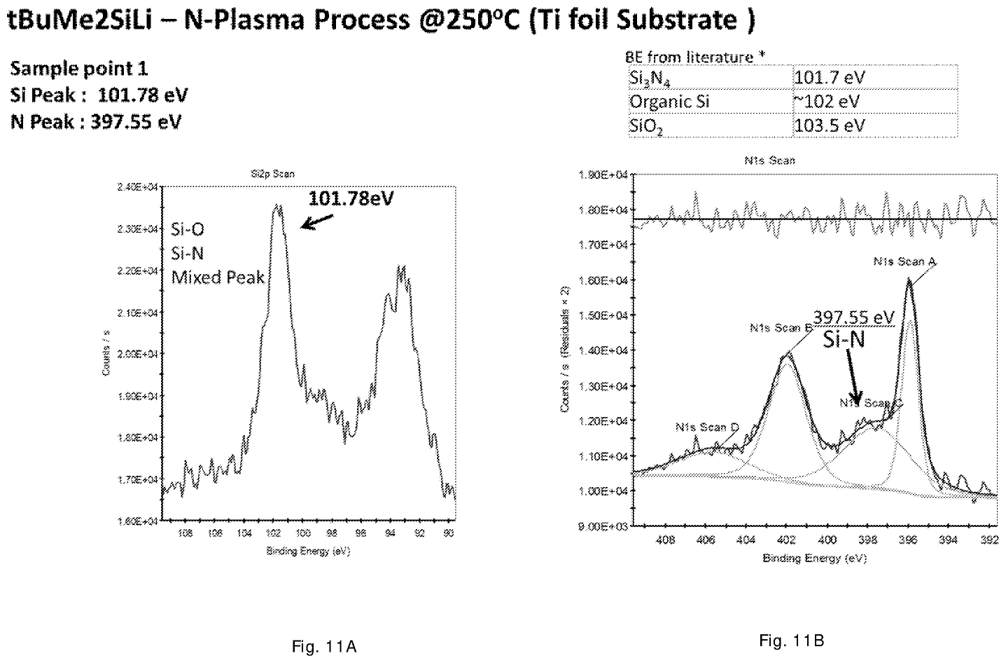

FIG. 11A is the XPS spectra (Intensity in absorbance units as a function of binding energy in eV) of Si 2p corresponding to the Ti foil substrate coated with tBuMe₂SiLi using N₂ Plasma according to another exemplary embodiment of the invention.

FIG. 11B is the XPS spectra (Intensity in absorbance units as a function of binding energy in eV) of N 1 s corresponding to the Ti foil substrate coated with tBuMe₂SiLi using N₂ Plasma according to another exemplary embodiment of the invention.

These results show that tBuMe₂SiLi is a suitable coating material and/or that Ti foil is a suitable substrate for additional embodiments of the invention. Alternatively or additionally, these results show that ALD with tBuMe₂SiLi can result in Lithiated Silicon Nitrides by reacting with N₂ plasma. This is believed to be a new reaction.

### Example 8

### Use of tBuMe₂SiNa to Deposit NaₓSi_{y}O_{z} On HE-NMC

In order to further demonstrate the wide applicability of the ALD treatment procedure presented above, the procedure was used to apply tBuMe₂SiNa to HE-NMC.

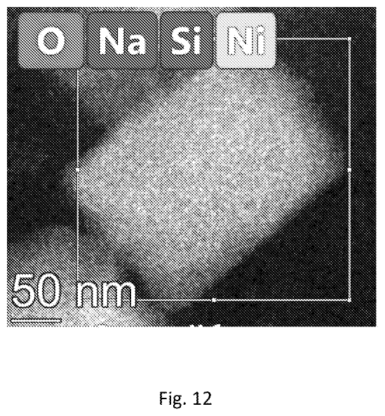

FIG. 12 is a STEM-HAADF (Scanning Transmission Electron Microscopy High-Angle Annular Dark-Field) image of tBuMe₂SiNa coated substrate of HE-NMC according to another exemplary embodiment of the invention.

These results show that tBuMe₂SiNa is a suitable coating material. The fact that it coats HE-NMC suggests that it can be used to coat other substrates.

### Example 9

### Use of Alk₃GeLi to Deposit LiₓGe_{y}O_{z} on HE-NMC

In order to further demonstrate the wide applicability of the ALD treatment procedure presented above, the procedure was used to apply Alk₃GeLi to HE-NMC.

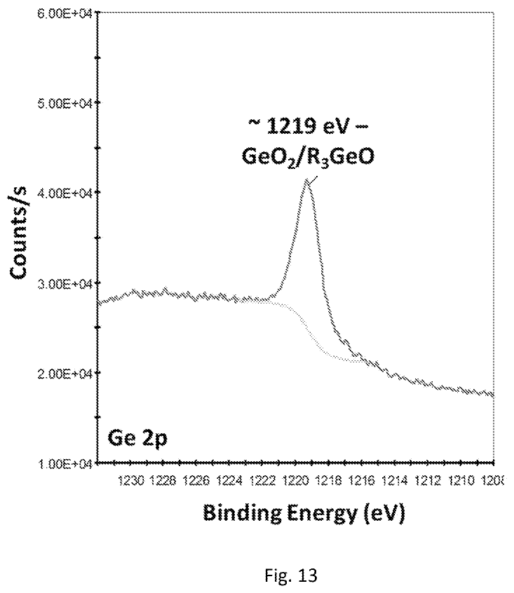

FIG. 13 is the XPS spectra (Intensity in absorbance units as a function of binding energy in eV) of Ge 2p corresponding to the HE-NMC substrate coated with Alk₃GeLi according to another exemplary embodiment of the invention.

These results show that Alk₃GeLi is a suitable coating material. The fact that it coats HE-NMC suggests that it can be used to coat other substrates.

### Example 10

### Use of [(Alk₃Si)₄Al]Li to Deposit LiₓSi_{y}O_{z}—Al_{w} on TiO₂

In order to further demonstrate the wide applicability of the ALD treatment procedure presented above, the procedure was used to apply [(Alk₃Si)₄Al]Li to TiO₂.

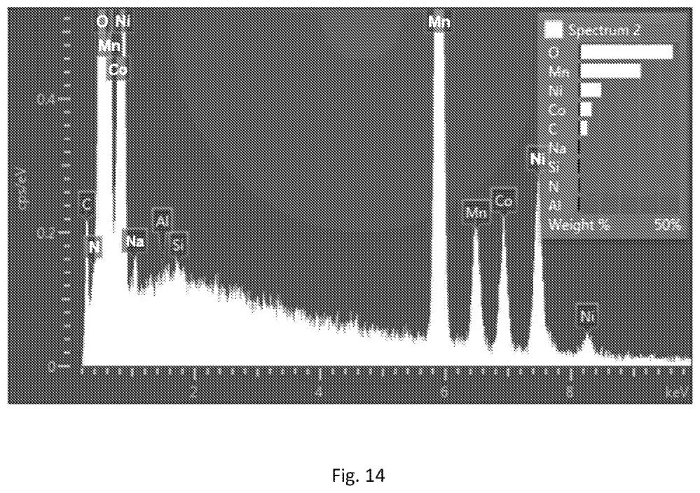

FIG. 14 is an EDS profile (counts as a function of energy in KeV) of a HENCM substrate coated with [(Alk₃Si)₄Al]Li according to another exemplary embodiment of the invention.

These results show that [(Alk₃Si)₄Al]Li is a suitable coating material. This is interesting because this trifunctional precursor can act as a source of three elements, Li, Si and Al. The fact that [(Alk₃Si)₄Al]Li coats TiO₂ suggests that it can be used to coat other substrates.

### Example 11

### Use of (NMe₂)(tBu)₂SiLi to Deposit LiₓSi_{y}O_{z}—N, on Gd and S Doped TiO₂

In order to further demonstrate the wide applicability of the ALD treatment procedure presented above, the procedure was used to apply (NMe₂)(tBu)₂SiLi to Gd and S doped TiO₂.

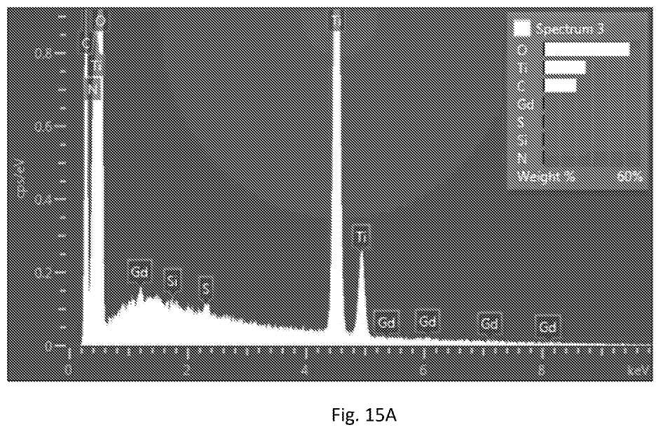

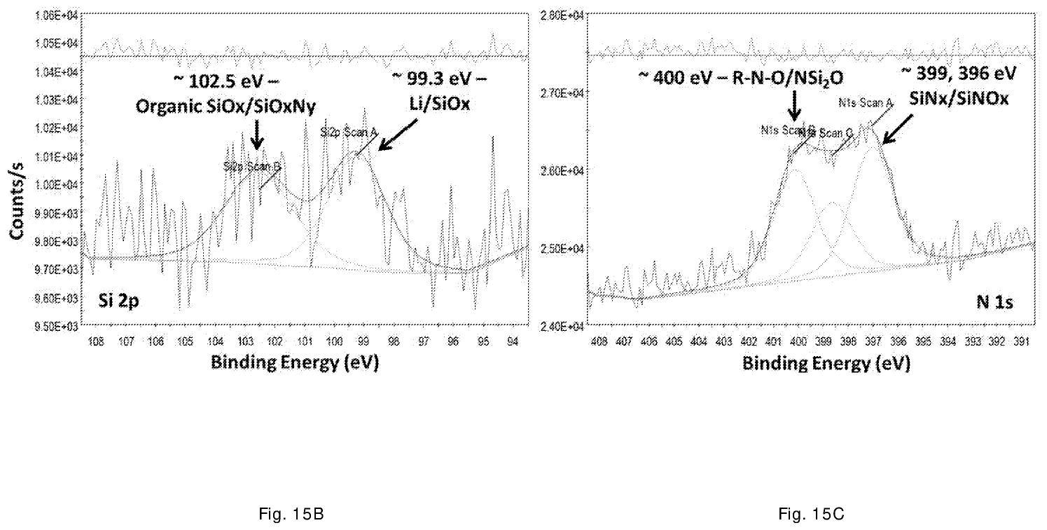

FIG. 15A is an EDS profile (counts as a function of energy in KeV) of a Gd and S doped TiO₂ substrate coated with (NMe₂)(tBu)₂SiLi according to another exemplary embodiment of the invention.

FIG. 15B is the XPS spectra (Intensity in absorbance units as a function of binding energy in eV) of Si 2p corresponding to the Gd and S doped TiO₂ substrate coated with (NMe₂)(tBu)₂SiLi according to an exemplary embodiment of the invention.

FIG. 15C is the XPS spectra (Intensity in absorbance units as a function of binding energy in eV) of N 1 s corresponding to the Gd and S doped TiO₂ substrate coated with (NMe₂)(tBu)₂SiLi according to an exemplary embodiment of the invention.

These results show that (NMe₂)(tBu)₂SiLi is a suitable coating material. This is interesting because this trifunctional precursor can act as a source of three elements, Li, Si and N. The fact that (NMe₂)(tBu)₂SiLi coats Gd and S doped TiO₂ suggests that it can be used to coat other substrates.

### Example 12

### tBuMe₂SiLi-TMEDA Coated Gd and S Doped TiO₂

In order to further demonstrate the wide applicability of the ALD treatment procedure presented above, the procedure was used to apply tBuMe₂SiLi-TMEDA to Gd and S doped TiO₂.

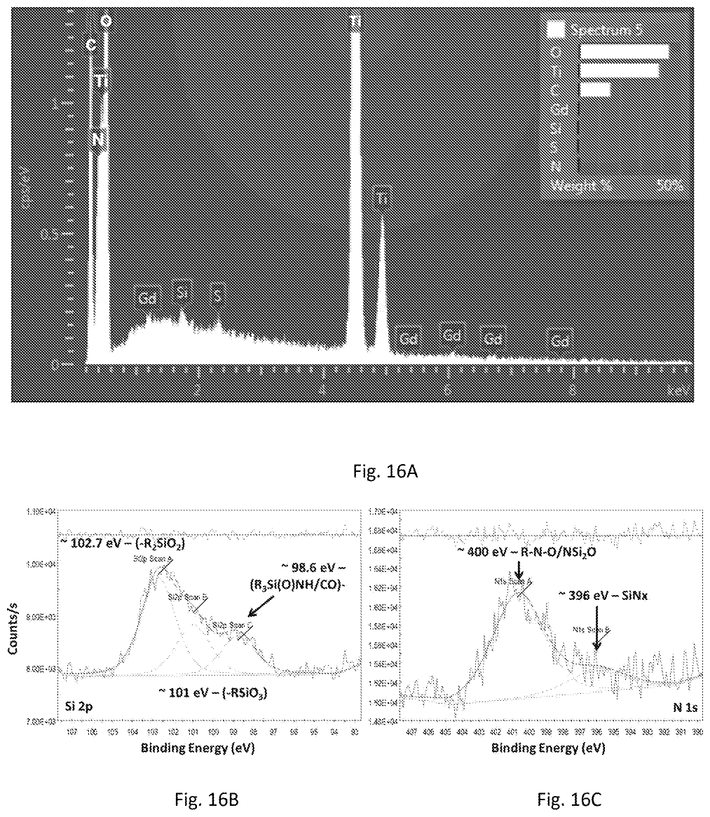

FIG. 16A is an EDS profile (counts as a function of energy in KeV) of Gd and S doped TiO₂ substrate coated with tBuMe₂SiLi-TMEDA according to an exemplary embodiment of the invention.

FIG. 16B is the XPS spectra (Intensity in absorbance units as a function of binding energy in eV) of Si 2p corresponding to the Gd and S doped TiO₂ substrate coated with tBuMe₂SiLi-TMEDA according to an exemplary embodiment of the invention.

FIG. 16C is the XPS spectra (Intensity in absorbance units as a function of binding energy in eV) of N 1 s corresponding to the Gd and S doped TiO₂ substrate coated with tBuMe₂SiLi-TMEDA according to an exemplary embodiment of the invention.

These results show that tBuMe₂SiLi-TMEDA is a suitable coating material. This is interesting because this trifunctional precursor can act as a source of three elements, Li, Si and N. The fact that tBuMe₂SiLi-TMEDA coats Gd and S doped TiO₂ suggests that it can be used to coat other substrates.

### Example 13

### TMA+SiLi₂tBuMe Coated TiO₂

In order to further demonstrate the wide applicability of the ALD treatment procedure presented above, the procedure was used to apply SiLi₂tBuMe to TiO₂.

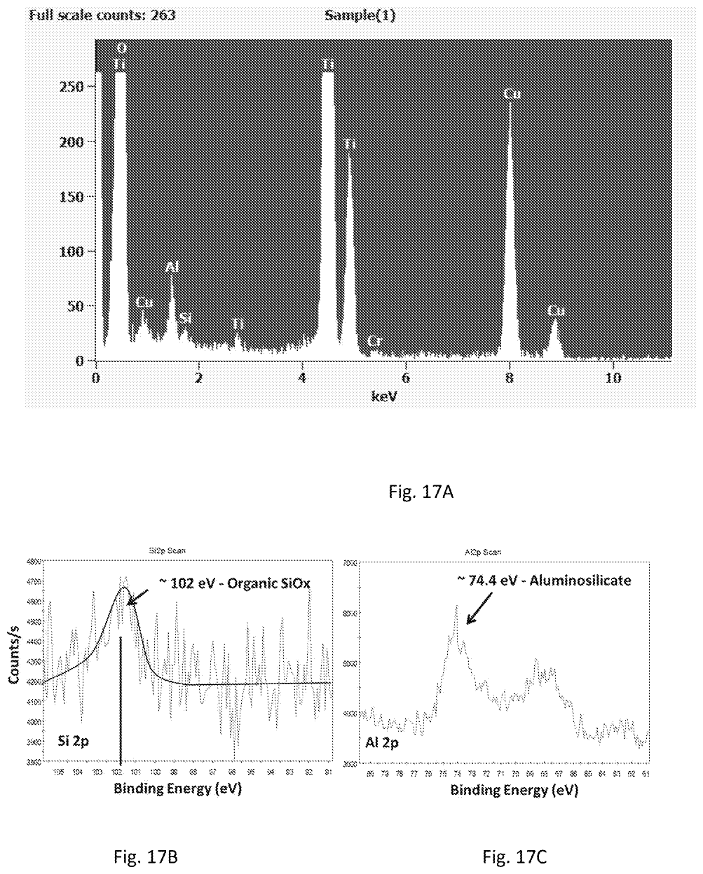

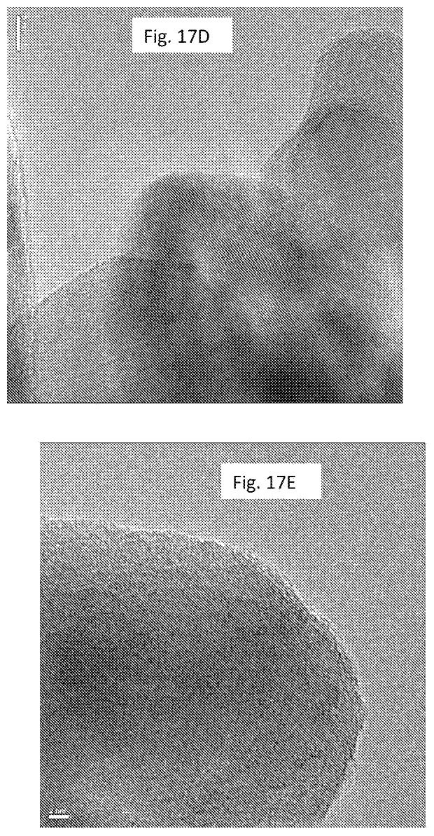

FIG. 17A is an EDS profile (counts as a function of energy in KeV) of TiO₂ substrate coated with Trimethyl Aluminum and, SiLi₂tBuMe Ozone as a source of Li, Si, and Al respectively according to an exemplary embodiment of the invention.

FIG. 17B is the XPS spectra (Intensity in absorbance units as a function of binding energy in eV) of Si 2p corresponding to the TiO₂ substrate coated with Trimethyl, SiLi₂tBuMe Aluminum and Ozone as a source of Li, Si, Al and O respectively according to an exemplary embodiment of the invention.

FIG. 17C is the XPS spectra (Intensity in absorbance units as a function of binding energy in eV) of Al 2p corresponding to the TiO₂ substrate coated with Trimethyl, SiLi₂tBuMe Aluminum and Ozone as a source of Li, Si, Al and O respectively according to an exemplary embodiment of the invention.

FIG. 17D is an HR-TEM picture of coated TiO₂ particles coated with SiLi₂tBuMe, Trimethyl Aluminum and Ozone.

FIG. 17E is an HR-TEM picture of TiO₂ particles coated with SiLi₂tBuMe, Trimethyl Aluminum and Ozone.

These results show that SiLi₂tBuMe is a suitable coating material and/or confirm that that TiO₂ is a suitable substrate for additional embodiments of the invention. Alternatively or additionally, these results suggest that SiL₂tBuMe can be used in ALD to coat a wide variety of substrates.

1. A method comprising:
performing atomic layer deposition (ALD) or molecular layer deposition (MLD) of at least one volatile organo silyl compound selected from the group consisting of tBuMe₂SiLi, tBuMe₂SiNa, Et₃SiLi, Alk₃GeLi, [(Alk₃Si)₄Al]Li, (NMe₂)(tBu)₂SiLi, tBuMe₂SiLi-TMEDA and +tBuMe₂SiLi+TMA and ozone on a substrate.

2. (canceled)

3. A method according to claim 1, wherein said volatile organo silyl compound comprises tBuMe₂SiLi.

4. A method according to any one of claim 1, wherein said substrate comprises at least one item selected from the group consisting of an electrode material, a semiconductor material and a metal foil.

5. A method according to claim 4, wherein said electrode material comprises at least one item selected from the group consisting of 0.35Li₂MnO₃·0.65LiNi_{0.35}Mn_{0.45}Co_{0.20}O₂ (HE-NMC), LCO, NCM 622 (LiNi_{0.6}Mn_{0.2}Co_{0.20}O₂), NCM85(LiNi_{0.85}Mn_{0.1}Co_{0.05}O₂), LTO (Li₂TiO₃), TiO₂, LNMO (LiNi_{0.5}Mn_{1.5}O₄), NVPF (Na₃V₂(PO₄)₂F₃), and LNO (LiNiO₂).

6. A method according to claim 5, wherein said substrate comprises 0.35Li₂MnO₃·0.65LiNi_{0.35}Mn_{0.45}Co_{0.20}O₂ (HE-NMC).

7. A method according to claim 4, wherein said semiconductor material comprises at least one item selected from the group consisting of Si wafers, TiO₂ particles, TiO₂ particles (Gd and S Doped with sufficient material to enhance ssNMR signal).

8. A method according to claim 4, wherein said metal foil comprises at least one item selected from the group consisting of copper (Cu) foil and Titanium (Ti) foil.

9. A method according to claim 1, wherein said ALD occurs in a vacuum reactor.

10. A method according to claim 1, wherein said volatile organo silyl compound is maintained at ≥145° C.

11. A method according to claim 9, wherein said vacuum reactor is maintained at a temperature of at least 75° C.

12. A method according to claim 1, comprising an ALD cycle including at least 0.025 sec pulse time for substrate followed by a at least 30 s dwell time and at least 0.01 s long ozone pulse with at least 30 sec dwell time.

13-14. (canceled)

15. An article of manufacture comprising:
a substrate selected from the group consisting of 0.35Li₂MnO₃·0.65LiNi_{0.35}Mn_{0.45}Co_{0.20}O₂ (HE-NMC), LCO, NCM 622 (LiNi_{0.6}Mn_{0.2}Co_{0.20}O₂), NCM85(LiNi_{0.5}Mn_{0.1}Co_{0.05}O₂), LTO(Li₂TiO₃), TiO₂ LNMO (LiNi_{0.5}Mn_{1.5}O₄), NVPF (Na₃V₂(PO₄)₂F₃), LNO (LiNiO₂), TiO₂) particles (Gd and S doped), copper (Cu) foil and Titanium (Ti) foil coated with LiₓSi_{y}O_{z}.

16. An article of manufacture according to claim 15, wherein said LiₓSi_{y}O_{z} coating has a thickness of at least 2 nm.

17. An article of manufacture according to claim 15, wherein said LiₓSi_{y}O_{z} coating has a thickness of 5 nm or less.

18. An article of manufacture according to claim 15, wherein said substrate comprises 0.35Li₂MnO₃·0.65LiNi_{0.35}Mn_{0.45}Co_{0.20}O₂ (HE-NMC).

19. An article of manufacture according to claim 15, exhibiting a peak at 102.18 eV in X-ray photoelectron spectroscopy (XPS).

20. An article of manufacture according to claim 15, exhibiting four silicon chemical environments at 17 ppm, −20 ppm, −60 ppm, and −110 ppm in direct dynamic nuclear polarization (DNP) spectra with CPMG detection.

21. An article of manufacture according to claim 15, exhibiting ¹H nuclei, at 33 ppm, 27 ppm, 20 ppm, and 1.85 ppm by indirect dynamic nuclear polarization (DNP).

22. (canceled)

23. A battery comprising an article of manufacture according to claim 15 as an electrode, showing no signs of structural disintegration after 100 charge/discharge cycles as analyzed by high-resolution scanning electron microscopy (HR-SEM).

24-28. (canceled)

29. A method for improving the electrochemical performance of a 0.35Li₂MnO₃·0.65LiNi_{0.35}Mn_{0.45}Co_{0.20}O₂ (HE-NMC) cathode, comprising creating a thin film layer thereon by ALD, using tBuMe₂SiLi as a precursor of Li and Si.
